(19) United States
(12) Patent Application Publication
(10) Pub. No.: US 2025/0385484 A1
(43) Pub. Date: Dec. 18, 2025

(54) OPTICAL MODULE WITH THERMOELECTRIC COOLER HAVING SHAPED MOUNTING PART

(71) Applicant: Global Technology Inc., Ningbo (CN)

(72) Inventors: Jian-hong LUO, Ningbo (CN); Di WANG, Ningbo (CN); YiMeng XU, Ningbo (CN)

(21) Appl. No.: 18/816,478

(22) Filed: Aug. 27, 2024

(30) Foreign Application Priority Data
Jun. 17, 2024 (CN) 202410777401.1

(51) Int. Cl. H01S 5/024; H01S 5/00

(52) U.S. Cl. CPC H01S 5/02415; H01S 5/0014; H01S 5/0085

(57) ABSTRACT

The present disclosure provides an optical module, including a housing, a thermoelectric cooler, and an optical transmitter assembly. The thermoelectric cooler is disposed in the housing. The thermoelectric cooler includes a cold end and a hot end which are coupled to each other. The optical transmitter assembly includes an optical transmitting unit and an optical modulator. The optical modulator is optically coupled to the optical transmitting unit. The thermoelectric cooler further includes a protrusion part extending from an edge of the cold end. The optical transmitting unit is disposed at the cold end. At least a part of the optical modulator is disposed at the protrusion part.

### CROSS-REFERENCE TO RELATED APPLICATIONS

This non-provisional application claims priority under 35 U.S.C. § 119 (a) on Patent Application No(s). 202410777401.1 filed in China on Jun. 17, 2024, the entire contents of which are hereby incorporated by reference.

### BACKGROUND

### Technical Field

The present disclosure relates to an optical module.

### Related Art

With respect to modern high-speed communication network, optical modules are generally installed in an electronic communication apparatus for various applications including, but not limited to, internetwork data center, Cable TV broadband, and fiber to the home (FTTH). With the improvement of the performance of the electronic communication apparatus and the increase in demand for communication bandwidth for various network services, the existing optical modules still present some problems, such as small internal accommodation space and high power consumption, to be solved.

Therefore, how to provide optical modules with small size, an internal space having better space utilization and low power consumption while increasing bandwidth and transmission rate is one of the most challenging topics in this technical field.

### SUMMARY

According to one embodiment of the present disclosure, an optical module includes a housing, a thermoelectric cooler, and an optical transmitter assembly. The thermoelectric cooler is disposed in the housing. The thermoelectric cooler includes a cold end and a hot end which are coupled to each other. The optical transmitter assembly includes an optical transmitting unit and an optical modulator. The optical modulator is optically coupled to the optical transmitting unit. The thermoelectric cooler further includes a protrusion part extending from an edge of the cold end. The optical transmitting unit is disposed at the cold end. At least a part of the optical modulator is disposed at the protrusion part.

According to another embodiment of the present disclosure, an optical module includes a housing, a thermoelectric cooler, an optical transmitter assembly, and an electrical feedthrough. The thermoelectric cooler is disposed in the housing. The thermoelectric cooler includes a cold end, a hot end, a plurality of thermoelectric material components, and a conductive terminal. The thermoelectric material components couple the cold end to the hot end, and the conductive terminal is coupled to at least one of the plurality of thermoelectric material components. The electrical feedthrough is coupled to the housing, and the optical transmitter assembly is electrically coupled to the electrical feedthrough. The thermoelectric cooler further includes a protrusion part extending from an edge of the cold end. The protrusion part is disposed between the cold end and the electrical feedthrough, and the conductive terminal is disposed between the cold end and the electrical feedthrough and spaced apart from the protrusion part.

According to still another embodiment of the present disclosure, an optical module includes an optical coupler, an optical transmitter assembly, a thermoelectric cooler, and an electrical feedthrough. The optical transmitter assembly is optically coupled to the optical coupler. The thermoelectric cooler includes a cold end, a hot end, and a plurality of thermoelectric material components, and the thermoelectric material components couple the cold end to the hot end. The electrical feedthrough is electrically coupled to the optical transmitter assembly. The thermoelectric cooler further includes a protrusion part extending from an edge of the cold end. The protrusion part is disposed between the cold end and the electrical feedthrough. A part of the optical transmitter assembly is disposed at the cold end, and another part of the optical transmitter assembly is disposed at the protrusion part.

### BRIEF DESCRIPTION OF THE DRAWINGS

The present disclosure will become better understood from the detailed description given hereinbelow and the accompanying drawings which are given by way of illustration only and thus are not intended to limit the present disclosure and wherein:

FIG. 1 is a perspective view of an optical module according to one embodiment of the present disclosure;

FIG. 2 is a top view of the optical module in FIG. 1;

FIG. 3 is a schematic view showing an optical path of the optical module in FIG. 2;

FIG. 4 is a side view of an optical coupling configuration in FIG. 1; and

FIG. 5 is a schematic view showing that an optical module according to one embodiment of the present disclosure is applied to an optical transceiver.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

According to an optical module known to the inventor, a thermoelectric cooler (TEC) is disposed below the optical transmitter assembly to function as a thermal management device that is capable of transmitting thermal energy generated by the optical transmitter assembly. The thermoelectric cooler may have a conductive terminal electrically coupled to external circuits, which is configured to be electrically coupled to external circuits through an electrical feedthrough. The external circuits are capable of outputting control signals to control the temperature of the optical transmitter assembly. Further, the thermoelectric cooler may receive control signals through the conductive terminal, and may generate a temperature difference between the cold end and the hot end due to Peltier effect. Generally, from a top view, the conductive terminal of the thermoelectric cooler is disposed at left or right side of the optical transmitter assembly along a transverse direction of the optical module. Inventors found that the conductive terminal of the thermoelectric cooler is changed to be disposed at rear side of the optical transmitter assembly along the longitudinal direction of the optical module such that a signal transmission path between the optical transmitter assembly and the electrical feedthrough becomes longer, which in turn leads to the problem of serious high-frequency signal loss.

According to one embodiment of the present disclosure, the thermoelectric cooler includes a protrusion part that is coupled to the cold end, so that the thermoelectric cooler has a shaped part (i.e., protrusion part) where the optical transmitter assembly is disposed. Therefore, in the case where conductive terminal of the thermoelectric cooler is disposed between the cold end and the electrical feedthrough, a part of the optical modulator may be disposed at the protrusion part to be close to the electrical feedthrough, allowing the temperature of the optical modulator to be stably controlled, and allowing the high-frequency signal loss to be reduced due to a short signal transmission path from the electrical feedthrough to the optical modulator.

Besides, in a dense wavelength division multiplexing (DWDM) system known to the inventor, multiple optical modules having constant wavelength are usually used, which presents some problems to be solved, such as high cost of management and large storage quantities. According to one embodiment of the present disclosure, the optical transmitter assembly uses a tunable laser diode to reduce the cost of operation and maintenance.

Some or all of the technical features disclosed in one or more embodiments of the present disclosure may be combined to achieve corresponding effects.

The term “couple” or “coupled to” refers to any connection, link, or the like. Moreover, the term “optically couple” or “optically coupled to” refers to a relationship where light is transmitted (imparted) from a device to another. Unless otherwise specified, devices that “couple” or “coupled to” each other do not need to be directly connected to each other and may be separated by intervening objects.

The term substantially, as generally referred to herein, refers to a degree of precision within acceptable tolerance that accounts for and reflects minor real-world variation due to material composition, material defects, and/or limitations/peculiarities in manufacturing processes. Such variation may therefore be said to achieve largely, but not necessarily wholly, the stated characteristic.

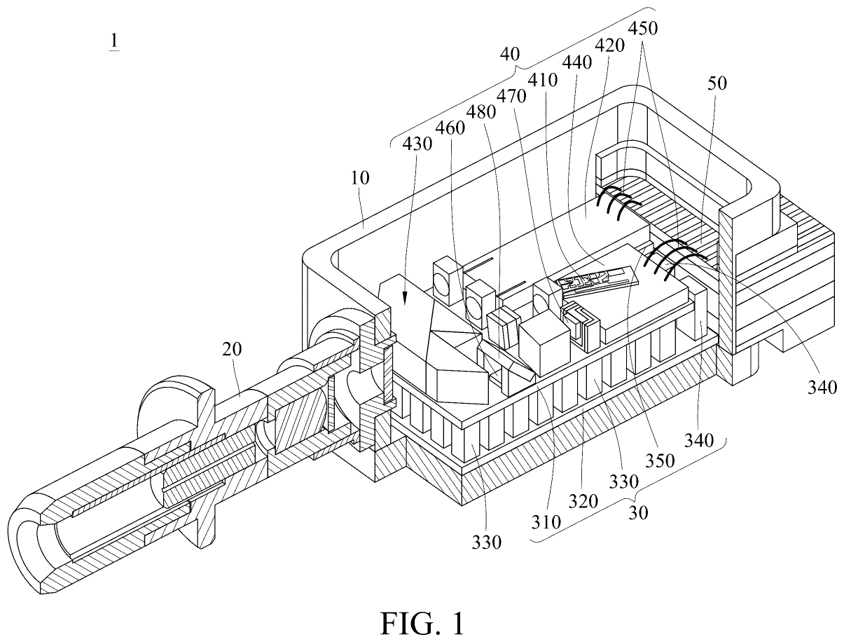

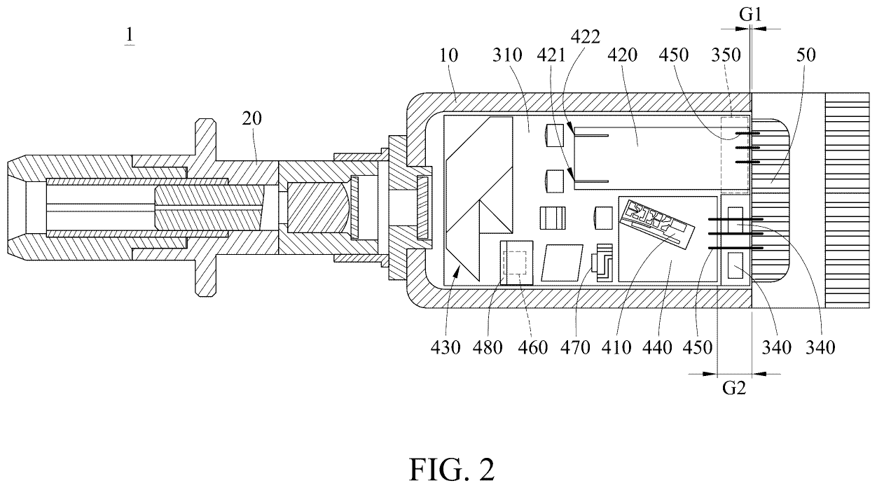

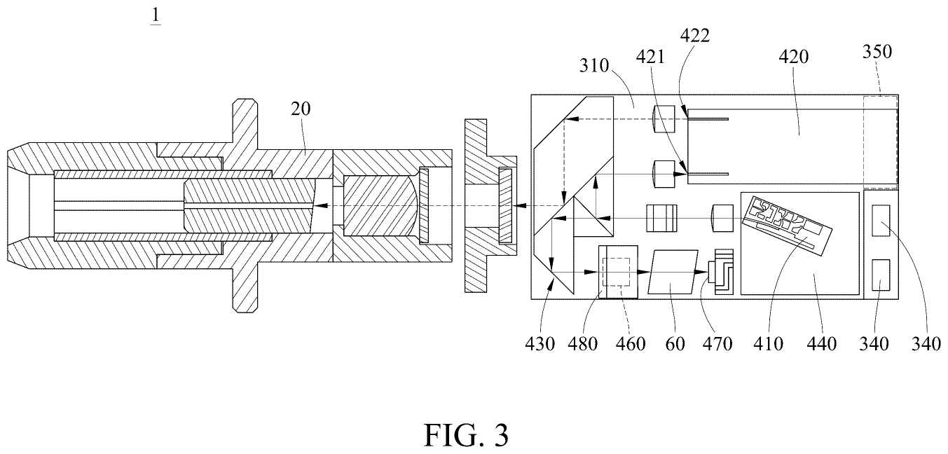

Please refer to FIGS. 1 to 3. FIG. 1 is a perspective view of an optical module 1 according to one embodiment of the present disclosure, FIG. 2 is a top view of the optical module 1 in FIG. 1, and FIG. 3 is a schematic view showing an optical path of the optical module 1 in FIG. 2. In this embodiment, the optical module 1 may include a housing 10, an optical coupler 20, a thermoelectric cooler 30, an optical transmitter assembly 40, and an electrical feedthrough 50. For illustration purposes, a part of the housing 10 is omitted in FIGS. 1 and 2, and the housing 10 is omitted in FIG. 3. The optical module 1 may be understood as a transmitter optical subassembly (TOSA) or an optical transceiver.

The housing 10 may be a housing made of metal. The housing 10 may be understood as a hermetic housing or a non-hermetic housing configured to encapsulate laser diodes. In one embodiment, the housing 10 may be an outer housing of the optical transceiver. In one embodiment, the housing 10 may be a base or a metal box that supports optical devices.

The optical coupler 20 may be disposed within an accommodation space defined by the housing 10. In one embodiment, at least a part of the optical coupler 20 may extend out of the housing 10. The optical coupler 20 may be understood as an optical fiber connector or a fiber connector receptacle, and an optical fiber (not shown) may be inserted in the optical coupler 20 to be optically coupled to the optical transmitter assembly 40. In one embodiment, the optical coupler 20 may be an MPO connector. In one embodiment, the optical coupler 20 may be an LC connector.

The thermoelectric cooler 30 may be accommodated in the housing 10, and the thermoelectric cooler 30 may include a cold end 310 and a hot end 320 which are coupled to each other. The thermoelectric cooler 30 may be understood as a cooling chip, and each of the cold end 310 and the hot end 320 may be understood as a metal sheet or a ceramic sheet with appropriate thermal conductivity.

The optical transmitter assembly 40 may be accommodated in the housing 10 and disposed at the thermoelectric cooler 30. In one embodiment, the optical transmitter assembly 40 may include an optical transmitting unit 410 and an optical modulator 420. The optical transmitting unit 410 and the optical modulator 420 may be disposed at the cold end 310 of the thermoelectric cooler 30. The optical modulator 420 may have an optical receiving port 421 and an optical transmitting port 422 at the same side thereof. The optical receiving port 421 may be optically coupled to the optical transmitting unit 410, and the optical transmitting port 422 may be optically coupled to the optical coupler 20. In one embodiment, the optical transmitter assembly 40 may further include an optical path folding assembly 430. The optical path folding assembly 430 may be configured to fold an optical axis of the optical transmitting unit 410, so that the optical transmitting unit 410 is optically coupled to the optical receiving port 421. The optical path folding assembly 430 may be configured to fold an optical axis of the optical modulator 420, so that the optical transmitting port 422 is optically coupled to the said optical fiber inserted in the optical coupler 20. In one embodiment, the optical transmitter assembly 40 may further include, but not limited to, a passive device, such as a wavelength division multiplexer, a collimating lens and an optical isolator, and/or an active device such as a laser driver chip. These devices may be disposed at the cold end 310 of the thermoelectric cooler 30. In one embodiment, the optical transmitter assembly 40 may include an optical transmitting unit 410, an optical modulator 420, an optical path folding assembly 430, a collimating lens, and an optical isolator. The optical transmitting unit 410 may be understood as a laser diode. In one embodiment, the optical transmitting unit 410 may be a tunable laser diode or a continuous wave (CW) laser. The optical modulator 420 may be understood as a Mach-Zehnder modulator, such as a thin-film lithium niobate modulator and a silicon photonic chip, which is allowed to provide the optical transmitter assembly 40 having high bandwidth and high signal transmission rate. The optical path folding assembly 430 may be understood as an assembly configured by a plurality of prisms, an assembly configured by a plurality of reflection lenses, or an assembly configured by one or more prisms and one or more reflection lenses.

The electrical feedthrough 50 may be disposed at the housing 10, and the optical transmitter assembly 40 may be electrically coupled to the electrical feedthrough 50. In one embodiment, a part of the electrical feedthrough 50 may extend out of the accommodation space of the housing 10, and another part thereof may be located in the housing 10. The optical transmitting unit 410 and the optical modulator 420 may be electrically coupled to the electrical feedthrough 50. The electrical feedthrough 50 may be understood as a ceramic circuit board.

According to one embodiment of the present disclosure, the thermoelectric cooler 30 may further include a plurality of thermoelectric material components 330 and at least one conductive terminal 340. As shown in FIGS. 1 and 2, the thermoelectric material components 330 may couple the cold end 310 and the hot end 320. The conductive terminal 340 may be coupled to at least one of the thermoelectric material components 330. In one embodiment, a plurality of thermoelectric material components 330 may include a plurality of p-type thermoelectric semiconductors and a plurality of n-type thermoelectric semiconductors that are coupled in series. The conductive terminal 340 may be electrically coupled to the electrical feedthrough 50 and one of the metal pads of the thermoelectric material components 330 disposed on a bottom thereof, allowing current to be provided to the thermoelectric material components 330 via the electrical feedthrough 50 and the conductive terminal 340. FIG. 1 exemplarily illustrates that the thermoelectric cooler 30 includes two separate conductive terminals 340, but the number of the conductive terminals 340 is not limited thereto.

According to one embodiment of the present disclosure, the conductive terminal 340 of the thermoelectric cooler 30 may be disposed between the cold end 310 and the electrical feedthrough 50. As shown in FIG. 1, in a longitudinal direction (i.e., a direction from the optical coupler 20 to the electrical feedthrough 50) of the optical module 1, each conductive terminal 340 may be disposed between the cold end 310 and the electrical feedthrough 50. As shown in FIG. 2, in one embodiment, the conductive terminal 340 may be a metal pillar, and a top of the metal pillar (conductive terminal 340) may be disposed between the cold end 310 and the electrical feedthrough 50.

According to one embodiment of the present disclosure, the thermoelectric cooler 30 may further include a protrusion part 350 extending from an edge of the cold end 310. The conductive terminal 340 and the protrusion part 350 may be disposed between the cold end 310 and the electrical feedthrough 50, and the conductive terminal 340 may be spaced apart from the protrusion part 350. As shown in FIGS. 1 and 2, in one embodiment, in the longitudinal direction of the optical module 1, the protrusion part 350 may be disposed between the cold end 310 and the electrical feedthrough 50. The top of the conductive terminal 340 may be spaced apart from the protrusion part 350. Besides, the conductive terminal 340 may not be disposed between the protrusion part 350 and the electrical feedthrough 50. In one implementation, the conductive terminal 340 and the protrusion part 350 may be arranged along a transverse direction of the optical module 1.

The optical transmitting unit 410 of the optical transmitter assembly 40 may be disposed at the cold end 310 of the thermoelectric cooler 30, and at least a part of the optical modulator 420 of the optical transmitter assembly 40 may be disposed at the protrusion part 350 of the thermoelectric cooler 30. As shown in FIGS. 2 and 3, in one embodiment, the optical modulator 420 may include a front section having the optical receiving port 421 and the optical transmitting port 422 and a rear section disposed opposite to the said front section. The front section of the optical modulator 420 may be disposed at the cold end 310, and the rear section of the optical modulator 420 may be disposed at the protrusion part 350.

According to one embodiment of the present disclosure, at least one of the thermoelectric material components 330 of the thermoelectric cooler 30 may be disposed below the protrusion part 350. In one embodiment, the protrusion part 350 may also function as a part of the cold end of the thermoelectric cooler 30. Therefore, it may be understood that the thermoelectric cooler 30 includes a first cold end 310 (the rest part other than the protrusion part 350) and a second cold end (protrusion part 350). In one embodiment, the protrusion part 350 may stick out without any thermoelectric material components 330 and conductive terminal 340 below thereof.

In the case where the conductive terminal 340 of the thermoelectric cooler 30 is disposed between the cold end 310 and the electrical feedthrough 50, because the thermoelectric cooler 30 includes the protrusion part 350 coupled to the cold end 310, a part of the optical modulator 420 may be disposed at the protrusion part 350 to be close to the electrical feedthrough 50, allowing the temperature of the optical modulator 420 to be stably controlled, and allowing the high-frequency signal loss to be reduced due to a shorter signal transmission path from the electrical feedthrough 50 to the optical modulator 420.

According to one embodiment of the present disclosure, the optical transmitter assembly 40 may further include a submount 440. The submount 440 may be understood as a submount. The optical transmitting unit 410 may be supported on the submount 440, and the optical transmitting unit 410 may be electrically coupled to the electrical feedthrough 50 via the submount 440. In one embodiment, the submount 440 may be wire bonded to the electrical feedthrough 50 through the metal wire 450, and the metal wire 450 may extend over the conductive terminal 340. The optical modulator 420 may also be wire bonded to the electrical feedthrough 50 through the metal wire 450.

According to one embodiment of the present disclosure, a minimum distance between the optical modulator 420 of the optical transmitter assembly 40 and the electrical feedthrough 50 may be shorter than a minimum distance between the submount 440 and the electrical feedthrough 50. As shown in FIG. 2, in the longitudinal direction of the optical module 1, a gap distance G1 between the rear section of the optical modulator 420 and the electrical feedthrough 50 may be shorter than a gap distance G2 between the submount 440 and the electrical feedthrough 50.

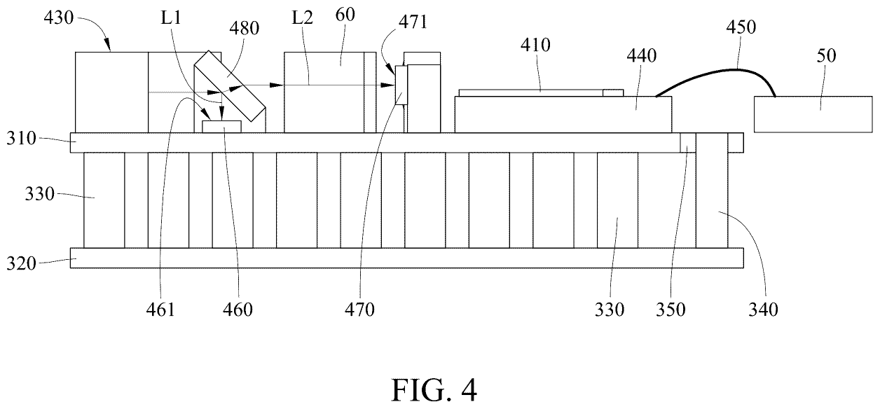

According to one embodiment of the present disclosure, the optical transmitter assembly 40 may further include a first monitoring photodiode (MPD) 460 and a second MPD 470. Please additionally refer to FIG. 4. FIG. 4 is a side view of an optical coupling configuration in FIG. 1. As shown in FIGS. 3 and 4, the first MPD 460 and the second MPD 470 may be optically coupled to the optical transmitting unit 410, and a light-receiving surface 461 of the first MPD 460 may be substantially perpendicular to a light-receiving surface 471 of the second MPD 470. In one embodiment, the optical path folding assembly 430 of the optical transmitter assembly 40 may be configured to fold the optical axis of the optical transmitting unit 410, so that the optical transmitting unit 410 is optically coupled to the MPD. Also, the optical transmitter assembly may further include a splitter 480, which is configured to split the optical signals generated by the optical transmitting unit 410 into two optical signals which are propagated to the first MPD 460 and the second MPD 470, respectively. As shown in FIG. 4, the optical signal emitted by the optical transmitter assembly 40 is incident on the splitter 480 after being folded by the optical transmitting unit 410, and the splitter 480 splits the optical signals into a sub-signal L1 propagated to the light-receiving surface 461 of the first MPD 460 and a sub-signal L2 propagated to the light-receiving surface 471 of the second MPD 470. Therefore, a feedback optical path distributed in a three-dimensional manner may be provided to improve the efficiency of the real-time monitoring of the optical transmitting unit 410 while realizing the compact configuration of the feedback optical path.

In one embodiment, as shown in FIGS. 3 and 4, an etalon 60 may be disposed in an optical coupling path between the splitter 480 and the second MPD 470. The etalon 60 may be a passive optical device and there is an interference effect between two planes in the optical direction thereof to form a comb-shaped transmission peak, so that a monitoring value of the first photodiode 460 is irrelevant to the wavelength, while a monitoring value of the second photodiode 470 is related to the wavelength. By adjusting a driving current of the optical transmitting unit 410 and a temperature of the thermoelectric cooler 30, the ratio of the monitoring values of the two photodiodes is kept stable to optimize optical wavelength.

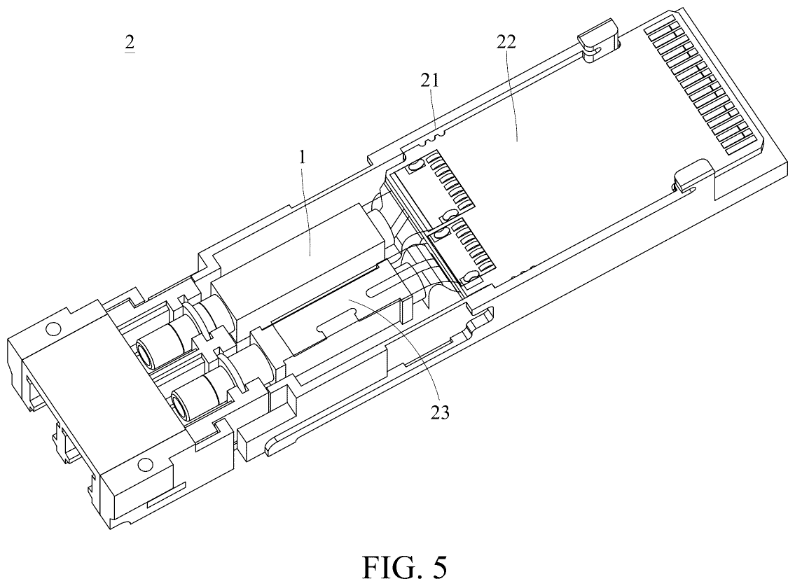

FIG. 5 is a schematic view showing that optical module 1 or 23 according to one embodiment of the present disclosure is applied to an optical transceiver 2. The optical transceiver 2 may include the optical module 1 as shown in FIG. 1, and may further include an outer housing 21, a printed circuit board assembly (PCBA) 22, and the optical module 23. For illustration purposes, an upper half part of the outer housing 21 is omitted in FIG. 5. The optical module 1 may be accommodated in the outer housing 21. The optical module 1 may be supported on an upper surface of the PCBA 22 or be electrically coupled to the PCBA 22. The optical module 1 in FIG. 5 may be understood as a TOSA, and the optical module 23 may be understood as a receiver optical subassembly (ROSA).

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An optical module, comprising:
a housing;
a thermoelectric cooler, disposed in the housing, wherein the thermoelectric cooler comprises a cold end and a hot end which are coupled to each other; and
an optical transmitter assembly, comprising an optical transmitting unit and an optical modulator, wherein the optical modulator is optically coupled to the optical transmitting unit;
wherein the thermoelectric cooler further comprises a protrusion part extending from an edge of the cold end, the optical transmitting unit is disposed at the cold end, and at least a part of the optical modulator is disposed at the protrusion part.

2. The optical module according to claim 1, wherein the thermoelectric cooler further comprises a conductive terminal and a plurality of thermoelectric material components, the plurality of thermoelectric material components couples the cold end to the hot end, the conductive terminal is coupled to at least one of the plurality of thermoelectric material components, and the conductive terminal is spaced apart from the protrusion part.

3. The optical module according to claim 1, further comprising an electrical feedthrough coupled to the housing, wherein the optical transmitting unit and the optical modulator are electrically coupled to the electrical feedthrough, and the protrusion part of the thermoelectric cooler is disposed between the cold end and the electrical feedthrough.

4. The optical module according to claim 3, wherein the thermoelectric cooler further comprises a conductive terminal, and the conductive terminal is disposed between the cold end and the electrical feedthrough.

5. The optical module according to claim 4, wherein the optical transmitter assembly further comprises a submount supporting the optical transmitting unit, the optical transmitting unit is electrically coupled to the electrical feedthrough via the submount, and a minimum distance between the optical modulator and the electrical feedthrough is shorter than a minimum distance between the submount and the electrical feedthrough.

6. The optical module according to claim 4, wherein the optical transmitter assembly further comprises a submount supporting the optical transmitting unit, the optical transmitting unit is electrically coupled to the electrical feedthrough via the submount, the submount is electrically coupled to the electrical feedthrough through a metal wire, and the metal wire extends over the conductive terminal.

7. The optical module according to claim 4, wherein the conductive terminal is not disposed between the protrusion part and the electrical feedthrough.

8. The optical module according to claim 1, wherein the optical transmitter assembly further comprises a first monitoring photodiode (MPD) and a second MPD, the first MPD and the second MPD are optically coupled to the optical transmitting unit, and a light-receiving surface of the first MPD is substantially perpendicular to a light-receiving surface of the second MPD.

9. An optical module, comprising:
a housing;
a thermoelectric cooler, disposed in the housing, wherein the thermoelectric cooler comprises a cold end, a hot end, a plurality of thermoelectric material components, and a conductive terminal, the plurality of thermoelectric material components couple the cold end to the hot end, and the conductive terminal is coupled to at least one of the plurality of thermoelectric material components;
an optical transmitter assembly; and
an electrical feedthrough, coupled to the housing, wherein the optical transmitter assembly is electrically coupled to the electrical feedthrough;
wherein the thermoelectric cooler further comprises a protrusion part extending from an edge of the cold end, the protrusion part is disposed between the cold end and the electrical feedthrough, and the conductive terminal is disposed between the cold end and the electrical feedthrough and spaced apart from the protrusion part.

10. The optical module according to claim 9, wherein the conductive terminal is not disposed between the protrusion part and the electrical feedthrough.

11. The optical module according to claim 9, wherein the optical transmitter assembly comprises an optical transmitting unit and an optical modulator, the optical transmitting unit is optically coupled to the optical modulator, the optical transmitting unit is disposed at the cold end, and at least a part of the optical modulator is disposed at the protrusion part.

12. The optical module according to claim 11, wherein the optical transmitter assembly further comprises a submount supporting the optical transmitting unit, the optical transmitting unit is electrically coupled to the electrical feedthrough via the submount, the submount is electrically coupled to the electrical feedthrough through a metal wire, and the metal wire extends over the conductive terminal.

13. The optical module according to claim 11, wherein the optical transmitter assembly further comprises a first MPD and a second MPD, the first MPD and the second MPD are optically coupled to the optical transmitting unit, and a light-receiving surface of the first MPD is substantially perpendicular to a light-receiving surface of the second MPD.

14. An optical module, comprising:
an optical coupler;
an optical transmitter assembly, optically coupled to the optical coupler;
a thermoelectric cooler, comprising a cold end, a hot end and a plurality of thermoelectric material components, wherein the plurality of thermoelectric material components couples the cold end to the hot end; and
an electrical feedthrough, electrically coupled to the optical transmitter assembly;
wherein the thermoelectric cooler further comprises a protrusion part extending from an edge of the cold end, the protrusion part is disposed between the cold end and the electrical feedthrough, a part of the optical transmitter assembly is disposed at the cold end, and another part of the optical transmitter assembly is disposed at the protrusion part.

15. The optical module according to claim 14, wherein the optical transmitter assembly comprises an optical transmitting unit and an optical modulator, the optical modulator is optically coupled to the optical transmitting unit, the optical transmitting unit is disposed at the cold end, and at least a part of the optical modulator is disposed at the protrusion part.

16. The optical module according to claim 15, wherein the thermoelectric cooler further comprises a conductive terminal, the optical transmitter assembly further comprises a submount supporting the optical transmitting unit, the conductive terminal is spaced apart from the protrusion part, the optical transmitting unit is electrically coupled to the electrical feedthrough via the submount, the submount is electrically coupled to the electrical feedthrough through a metal wire, and the metal wire extends over the conductive terminal.
